(19) United States
(12) Patent Application Publication
(10) Pub. No.: US 2003/0129545 A1
(43) Pub. Date: Jul. 10, 2003

(54) Method and apparatus for use of plasmon printing in near-field lithography

(76) Inventors: Pieter G. Kik, Pasadena, CA (US); Harry A. Atwater, So. Pasadena, CA (US)

Correspondence Address: Daniel L. Dawes, MYERS, DAWES & ANDRAS LLP, 19900 MacArthur Blvd, Ste 1150, Irvine, CA, 92612, US

(21) Appl. No.: 10/157,163

(22) Filed: May 29, 2002

Related U.S. Application Data
(60) Provisional application No. 60/301,796, filed on Jun. 29, 2001.
(60) Provisional application No. 60/341,907, filed on Dec. 18, 2001.

(51) Int. Cl. G03F 7/00

(52) U.S. Cl. 430/313; 430/5; 430/311; 430/396; 355/18; 355/77

(57) ABSTRACT

A method and apparatus for replicating patterns with a resolution well below the diffraction limit, uses broad beam illumination and standard photoresist. In particular, visible exposure (λ=410 nm) of silver nanoparticles in close proximity to a thin film of g-line resist (AZ 1813) can produce selectively exposed areas with a diameter smaller than λ/20. The technique relies on the local field enhancement around metal nanostructures when illuminated at the surface plasmon resonance frequency. The method is extended to various metals, photosensitive layers, and particle shapes.

### RELATED APPLICATIONS

The application is related to U.S. Provisional Patent Application serial No. 60/301,796 filed on May 29, 2001 and to U.S. Provisional Patent Application serial No. 60/341,907 filed on Dec. 18, 2001 to which priority is claimed under 35 USC 119 and which are incorporated herein by reference.

### BACKGROUND OF THE INVENTION

1. Field of the Invention

The invention relates to the field of nanophotolithography well below the diffraction limit of the light being used.

2. Description of the Prior Art

The continuing size reduction of integrated circuits to nanometer scale dimensions requires the development of new lithographic techniques. It is becoming increasingly difficult and complex to use the established method of optical projection lithography at the short optical wavelengths required to reach the desired feature sizes. For example, the use of wavelengths in the deep ultraviolet, the extreme ultraviolet (EUV), or the X-ray regime requires increasingly difficult adjustments of the lithographic process, including the development of new light sources, photoresists and optics. That this is seen as a major problem in the industry is clear from the large scale efforts to develop alternative approaches to nanolithography.

A relatively established method for the production of high resolution patterns is the use of focused particle beams, e.g. a focused electron beams or ion beams, that expose a resist layer as it is scanned across the substrate. Although this produces high resolution patterns, the sequential nature of the technique results in long writing times. Other sequential techniques involve the use of a local probes such as the tip of an atomic force microscope (AFM) or the tip of a near field scanning optical microscope (NSOM).

Two parallel approaches to nanolithography that do not require short-wavelength light are micro-contact printing, and the recently proposed evanescent interferometric lithography (EIL). The latter method employs the evanescent optical field set up near metallic gratings to achieve enhanced exposure.

What is needed is some type of methodology and apparatus which is not subject to each of the shortcomings of the prior art discussed above, and which can produce sub-wavelength structures using broad beam illumination of standard photoresist with visible light.

### BRIEF SUMMARY OF THE INVENTION

The invention is a method for performing nanolithography comprising the step of providing a mask having conductive nanostructures disposed thereon. The nanostructures have a plasmon resonance frequency that is determined by the dielectric properties of the surroundings and of the nanostructures as well as the nanostructure shape. The method continues with the steps of disposing the mask at least in close proximity to a smooth resist layer; illuminating the nanostructures with light at or near the frequency of the plasmon resonance frequency of the nanostructures to modify adjacent portions of the resist layer; and developing the resist layer to define plasmon printed, subwavelength patterns in the resist layer. The nanostructures are illuminated with p-polarized light at a glancing angle. However, it must be understood that there is no restriction on what angle can be used for illumination. The highest field enhancement in the resist occurs at glancing angle, but an enhanced field is obtained all around the particle at any angle of illumination. The optimum illumination geometry may be a compromise between optimum exposure contrast and practicality (normal incidence exposure being a conventional arrangement). Thus, the relevant design principle to “plasmon printing” is resonance and field enhancement, and not so much the geometry of the illumination arrangement.

In the illustrated embodiment the resist layer has a roughness less than 40 nm, so that features smaller than 40 nm on the resist layer can be resolved. However, it should be understood that the limiting requirement is that the resist cannot be thicker that the depth of enhanced exposure beneath the particle otherwise the resist will not be exposed all the way through. This means that the tolerable resist roughness depends on the chosen resist thickness. If the resist thickness is chosen to be 90% of the depth of enhanced exposure, the resist roughness should be less than ˜10% of its thickness.

In the illustrated embodiments the mask has conductive nanostructures disposed thereon which are comprised of Ag or Au particles with an average diameter of tens of nm or less selectively disposed on the mask. Typically, the nanostructures have an average diameter equal to or less than 40 nm.

What results is a pattern in the resist layer, typically a g-line photoresist layer, which can be developed to define a plasmon printed, subwavelength pattern in the resist layer with features with a size of the order of λ/10 or smaller, where λ is the wavelength of the light. However, what resist material is used depends on nanostructure material, e.g. if the resonance is in UV, a UV resist should be used. The illumination wavelength is chosen to achieve resonant excitation of the surface plasmon in the chosen materials system (i.e. particles, mask and substrate). Consequently, the resist of choice is a photoresist with a high sensitivity in the particular wavelength region where the plasmon resonance occurs. Thus, the method is not limited to a g-line resist, such as AZ 1813, as described in the illustrated embodiment below. In principle each nanoparticle material will have a different resonance frequency, and a corresponding illumination wavelength and resist sensitivity should be used.

The invention is also defined as an apparatus or means for performing the above methodology.

While the apparatus and method has or will be described for the sake of grammatical fluidity with functional explanations, it is to be expressly understood that the claims, unless expressly formulated under 35 USC 112, are not to be construed as necessarily limited in any way by the construction of “means” or “steps” limitations, but are to be accorded the full scope of the meaning and equivalents of the definition provided by the claims under the judicial doctrine of equivalents, and in the case where the claims are expressly formulated under 35 USC 112 are to be accorded full statutory equivalents under 35 USC 112. The invention can be better visualized by turning now to the following drawings wherein like elements are referenced by like numerals.

### BRIEF DESCRIPTION OF THE DRAWINGS

FIGS. 1a and 1b are graphs of the extinction coefficient of colloidal suspensions of Ag nanoparticles (diameter 41 nm) and gold nanoparticles (diameter 30 nm) respectively in water, showing enhanced absorption and scattering at the surface plasmon resonance frequency.

FIGS. 2a and 2b are diagrams illustrating plasmon printing. FIG. 2a shows the use of glancing angle illumination of using polarized visible light to produce enhanced resist exposure directly below the metal nanostructures on a mask layer. FIG. 2b shows the resulting pattern in the resist layer after development.

FIGS. 3a and 3b are two dimensional plots of the field intensity, E_{z}², obtained by three dimensional finite difference time domain simulations using the parameters listed in Table I. FIG. 3a shows the pattern relating to a 40 nm diameter silver particle. FIG. 3b shows the pattern relating to a 40 nm diameter gold particle on a 25 nm thick resist layer on glass under glancing angle illumination with p-polarized light. In both cases enhanced exposure is observed in an area with a diameter d<0.05 μm.

FIG. 4a is a diagram of an apparatus for providing the illumination utilized above. FIG. 4bs is a diagram of the sample holder, showing the approximate beam size. The beam direction is indicated by the arrows.

FIG. 5a is an atomic force microscopy image of a 75 nm thick exposed and developed AZ1813 resist layer, showing the presence 41 nm Ag particles on the surface (streaks) and a nanoscale depression attributed to locally enhanced resist exposure below a nanoparticle due to resonant excitation of a surface plasmon oscillation in the particle. FIG. 5b is a graph of height as a function of position of a cross-section through the imprint, showing a feature size of 50 nm (0.1 λ).

The invention and its various embodiments can now be better understood by turning to the following detailed description of the preferred embodiments which are presented as illustrated examples of the invention defined in the claims. It is expressly understood that the invention as defined by the claims may be broader than the illustrated embodiments described below.

### DETAILED DESCRIPTION OF THE PREFERRED EMBODIMENTS

The invention is an approach to nanolithography that produces sub-wavelength structures using broad beam illumination of standard photoresist with visible light. The technique is related to evanescent interferometric lithography, but does not rely on interferometry to produce the enhanced optical fields. The method is based on the plasmon resonance occurring in nanoscale metallic structures. When a metal nanoparticle is placed in an optical field, it exhibits a collective electron motion known as the surface plasmon oscillation. When the diameter of the particle is much smaller than the applied wavelength, the charge movement produces an oscillating dipole field around the particle. This can result in strongly enhanced electrical fields near the particle when the excitation occurs at the resonance frequency. For a spherical particle, the plasmon resonance occurs at the wavelength λ where ε_{particle}(λ)=−2×εₘₐₜᵣᵢₓ(λ), where ε_{particle} is the dielectric constant of the particle at the wavelength λ and where εₘₐₜᵣᵢₓ is the effective dielectric constant of the matrix at the wavelength λ, where the matrix is the medium in which the particles are disposed. An “effective” or “average” dielectric constant is used when the immediate surroundings consist of different materials. The magnitude of the field enhancement depends strongly on the carrier relaxation time in the nanoparticle. Metals with long relaxation times such as gold (τᵣₑₗₐₓ˜4 fs) and silver (τᵣₑₗₐₓ˜10 fs) show strong resonances in the visible and near-UV range.

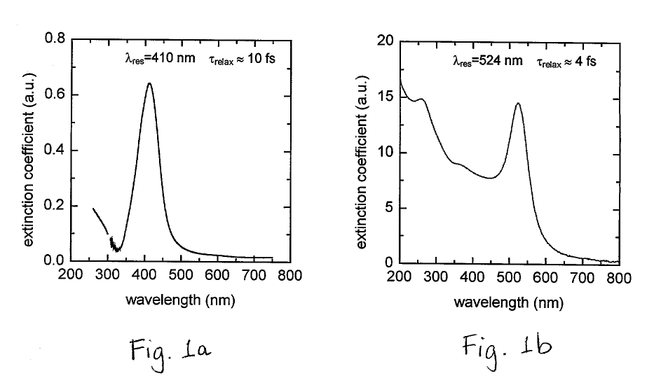

The occurrence of the plasmon resonance can be clearly observed in extinction measurements. FIG. 1a is a graph of the extinction coefficient as a function of wavelength and shows the extinction of an aqueous solution of Ag nanoparticles. The extinction coefficient of a sample is given by (1/D)ln(I₀/T) with D the sample thickness, I₀ the incident intensity, and T the transmitted intensity. A strong increase in the extinction is observed around 410 nm. This high extinction is the result of a strongly enhanced absorption and scattering. The resonantly excited electron oscillation induces enhanced resistive heating, while the oscillating dipole inside the particle generates dipole radiation adding to the total extinction.

FIG. 1(b) is a graph of the extinction coefficient as a function of wavelength which shows the extinction of a suspension of 30 nm diameter Au particles in water. This system also shows a plasmon resonance (λᵣₑₛ=524 nm), but additionally an absorption band is observed at shorter wavelengths. This absorption is the result of interband transitions in the gold nanoparticles, and does not contribute to the coherent plasmon oscillation.

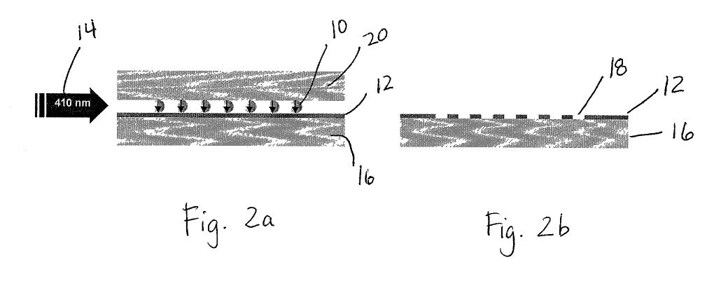

As shown above, illumination of metal nanoparticles at the plasmon resonance produces a strongly enhanced dipole field near the particle. This enhanced field can be used to locally expose a thin layer of resist. A schematic of the printing process is shown in FIGS. 2a and 2b, which illustrates this. In order to obtain intensity enhancement directly below a particle 10, the incoming light should be polarized approximately normal to the resist layer 12 (p-polarization), on a substrate 16 implying the need for glancing incidence exposure symbolically denoted by arrow 14 in FIG. 2a. The local field from particles 10 activate layer 12, which is then developed and etched in a conventional manner to open up a corresponding nano-hole 18 as shown in FIG. 2b. The idealized depictions of FIGS. 2a and 2b show in fact a plurality of uniformly spaced particles 10 fixed to a mask layer 20 made by conventional microlithographic or nanoscale fabrication techniques to form a corresponding plurality of nano-holes 18 through layer 12 on substrate 16. While mask layer 20 is described as having metal nanoparticles on its surface, it is expressly contemplated that having the nanoparticles embedded in the mask surface may be preferred for mask durability. Also, the mask should be transparent to the wavelength used for exposure. Finally, to be able to bring mask layer 20 into close proximity (<50 nm) to a substrate over large areas using standard technology, the use of a deformable mask layer 20 is preferred. Such deformable mask layer 20 is termed a “conformal mask”.

This approach is called “plasmon printing” because of its parallel nature and the use of surface plasmons for exposure. Plasmon printing enables the generation of sub-wavelength printed replicas of nanoscale structures in a parallel fashion, using standard photoresist and broad beam illumination in the visible.

The applicability of the methodology of the invention depends on the magnitude of the field enhancement effect, and the time-dependent field distribution around the metal nanoparticles 10. Field distributions during illumination in a simulated study were determined using 3D Finite Difference Time Domain (FDTD) calculations. The simulated geometry is comprised of a 40 nm diameter spherical particle 10 on a 25 nm thick resist layer 12 on glass 16. The surrounding medium is taken to have n=1 (air or vacuum). The simulations involved −10⁶ mesh points in a graded mesh density to obtain a high mesh density (2.2 nm cells) around metal particle 10 while keeping the total number of mesh lines manageable. Glancing angle illumination was simulated by a plane wave propagating in the +x direction. The wave was polarized in the z-direction to obtain maximum field enhancement above and below particle 10. The simulation parameters are listed in Table I below. The behavior of particles 10 was simulated by a Drude model with the dielectric function given by

εₘₑₜₐₗ(f)=1−(fₚ/f)² (1)

with fₚ the bulk plasma frequency and f the frequency of illumination 14. The values for fₚ in Table I were chosen to yield the correct surface plasmon resonance frequency as measured for nanoparticles 10 in water as observed in FIG. 1. The total length of the simulation was set to several times the relaxation time to approach the steady state amplitude of the field oscillation in and around particles 10. It should be noted that the effect of resist absorption on the plasmon resonance has not been taken into account in these calculations. A highly absorbing resist layer 12 may reduce the magnitude of the field enhancement.

TABLE I
Parameters used in the 3D Finite Difference
Time Domain Calculations.

| | Ag | Au |
|---|---|---|
| Diameter (nm) | 40 | 40 |
| fₚₗₐₛₘₐ | 1.47 × 10¹⁵ | 1.08 × 10¹⁵ |
| fᵣₑₗₐₓ | 10¹⁴ | 2.5 × 10¹⁴ |
| f_{exc} | 7.32 × 10¹⁴ | 5.59 × 10¹⁴ |
| λ_{exc} | 410 nm | 537 nm |
| ε_{glass} (λ_{exc}) (n) | 2.25 (1.5) | 2.25 (1.5) |
| ε_{resist (n)} | 2.91 (1.71) | 2.76 (1.66) |
| εₐᵢᵣ | 1 | 1 |
| # of steps | 10000 | 5000 |
| Δt | 2.73 × 10⁻¹⁸ | 3.58 × 10⁻¹⁸ |
| t_{end} | 2.73 × 10⁻¹⁴ | 1.79 × 10⁻¹⁴ |
| Optical cycles | 20 | 10 |

Where fₚₗₐₛₘₐ is the frequency of bulk plasma frequency; fᵣₑₗₐₓ is the electron collision frequency (in Hz); f_{exc} is the frequency of the light used to expose; λ_{exc} is the wavelength of the light used to expose; ε_{glass} (λ_{exc}) is the dielectric constant at λ_{exc} of the glass substrate and n is the corresponding refractive index; εᵣₑₛᵢₛₜ is the dielectric constant at λ_{exc} of the resist layer at the excitation wavelength and n is the index of refraction of resist 12. Since the refractive index of the materials used here depends significantly on the (exposure) wavelength, different values for the refractive index must be used when different excitation wavelengths are used. εₐᵢᵣ is the dielectric constant of air taken to be wavelength independent. “# of steps” refers to the number of time evolution steps undertaken in the finite difference calculation of the simulation. Δt is the magnitude of the time step in the FDTD calculations and t_{end} is the total simulated time and is consequently given by the product of #steps and Δt. Optical cycles refers to the number of optical cycles that fits in the total calculation time and is consequently given by the product of t_{end}×f_{exc}.

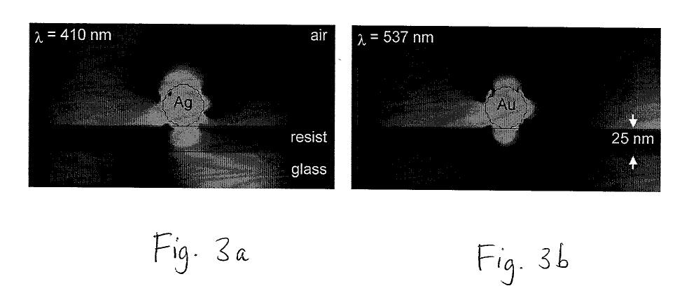

The incoming wave 14 is p-polarized, and consequently the main contribution to the total field strength directly beneath the particle is E_{z}. FIG. 3(a) shows a snapshot of E_{z}² around a 40 nm silver particle 10 near the end of the simulation. The image shows two fronts of high field to the left and right of particle 10 showing as broad dim features, and a strong opposing field inside particle 10 in an area where the external field is zero. This is the result of the 90° phase lag between exciting field and induced field associated with resonant excitation. Note that while particle 10 is excited at 410 nm, the area of enhanced exposure is only ˜20 nm in diameter. This suggests that in this type of geometry, it is possible to print features as small as λ/20. Since the field strength drops off gradually but rapidly with distance, the size of the exposed area will depend on the intensity and the duration of the exposure.

FIG. 3(b) shows E_{z}² around a 40 nm gold particle 10 near the end of the simulation. The region of enhanced exposure is smaller than in the case of silver, indicating a lower exposure contrast between patterned and unpatterned areas. The calculations shown in FIGS. 3a and 3b indicate that the minimum feature size most likely will be limited by practical issues such as fluctuations in intensity or mask-to-sample distance. To achieve pattern transfer, the resist should be exposed all the way through, and consequently the resist layer should be thinner than the depth beneath the particle in which an enhanced field is obtained. From FIGS. 3a and 3b this depth can be seen to be on the order of ˜25 nm for 40 nm diameter Ag nanoparticles and of the order of ˜15 nm for 40 nm diameter Au nanoparticles.

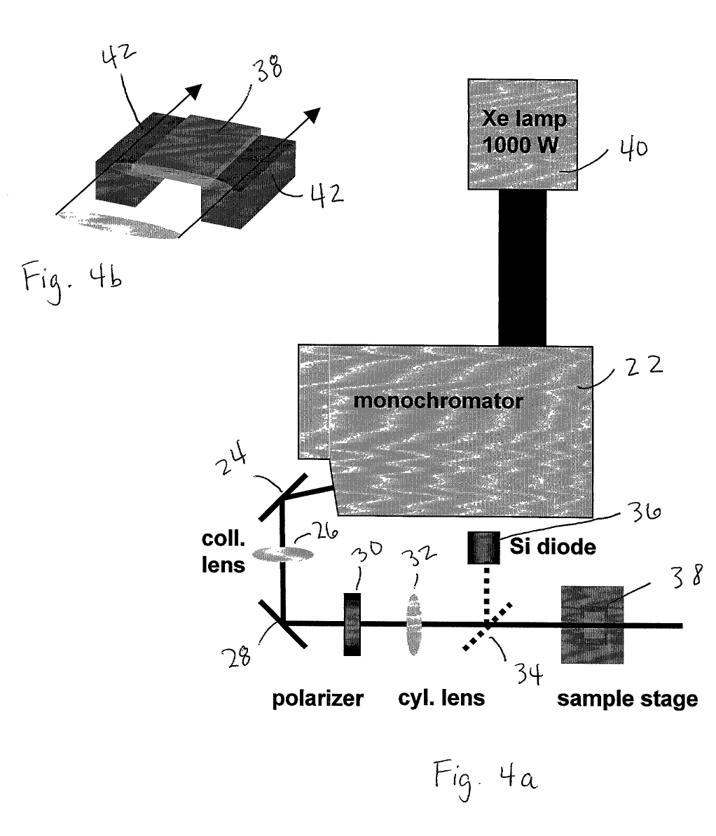

Initial experiments were performed aimed at obtaining a proof-of-principle. To avoid difficulties in achieving the desired nanoscale spacing between mask layer 20 and resist layer 12, instead of using a conventional mask the experiments involve 41 nm diameter silver nanoparticles which comprise mask layer 20 which are spray-deposited onto a thin resist layer 12. Glass substrates 16 (surface roughness <5 Å RMS) were coated with standard g-line resist 12 (AZ1813, Shipley) which has its maximum sensitivity in the wavelength range 300-450 nm. The resist 12 was diluted with AZ EBR dilutant (ratio AZ1813:EBR=1:4) and subsequently spin coated onto substrate 16 at 5000 rpm (60 s) producing a smooth ˜75 nm thick film 12. The smoothness is important since in the experiments ˜40 nm diameter features need to be resolved. As shown in the diagram of FIG. 4a the output of a 1000 W Xe arc lamp 40 was sent through a monochromator 22 set to a wavelength of 410 nm, reflected by mirror 24, collimated by lens 26, reflected again by mirror 28 and subsequently passed through a polarizer 30 to obtain polarization normal to the sample surface. The beam was vertically compressed using a cylindrical lens 32 to increase the power density, and sent to the sample 38 at glancing incidence. Incident power of illumination is sampled using a beam splitter 34 and Si diode 36. The sample 38 is suspended to prevent exposure by light scattered from the sample holder 42 as shown in FIG. 4b. The applied power densities were of the order of 1 mW/cm², and exposures times were in the range 10 s -300 s. After exposure the films were developed for 20 s in developer (MF317), mixed with water in a 1:1 ratio to slow down development. Conventional exposure of the 75 nm thick resist layers 12 showed normal development at these development conditions. The developed films 12 were investigated using contact mode atomic force microscopy.

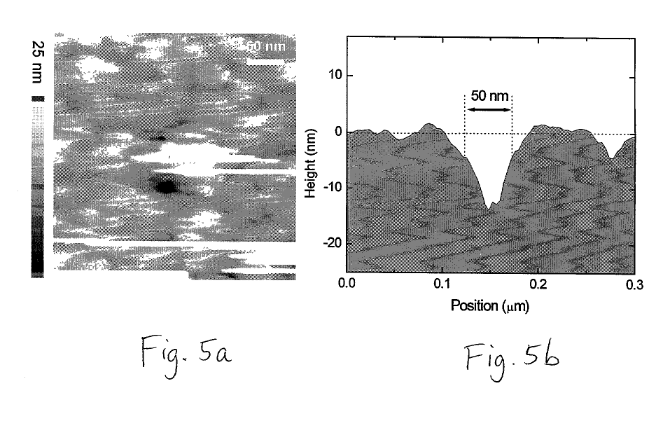

The developed films 12 were found to still have some residual nanoparticles 10 on the surface. Using the AFM tip it was possible to move the particles 10 over the surface, producing streaks in the AFM images. In addition to particles 10, nanoscale dips were observed in the resist film 12, suggesting enhanced exposure in sub-wavelength size areas. FIG. 5a shows an AFM scan of a 300×300 μm area, showing an approximately circular depression in the resist layer 12. FIG. 5b shows a cross-section through the depression, showing a lateral size of approximately 50 nm, and a depth of 12 nm, possibly limited by the AFM tip shape. It should be noted that the identification of these nanoscale imprints is not fully unambiguous due to the relatively large resist roughness after development. Experiments are underway to further investigate the effect of plasmon enhanced resist exposure.

The calculations and experiments presented here dealt exclusively with isolated 30-40 nm diameter metal particles 10. When larger particles are used, the field enhancement will eventually drop due to the excitation of multipolar oscillations in particles 10. Going to smaller particles 10, carrier relaxation due to surface scattering will eventually start to dominate the relaxation time, adversely affecting the field enhancement. It is expected that there will also be an effect of particle-particle interactions in more complex patterns, an effect dependant on the angle of incidence of exposure, and an effect due to the particle shape on the field enhancement.

Thus, it can now be understood that local field enhancement occurring around metal or conductive nanoparticles 10, when they are excited at the surface plasmon resonance frequency, can be used to print nanoscale features in thin resist layers 12. Feature sizes below λ/10 can be generated using visible illumination and standard g-line photoresist. No single number for resolution can be given for the achievable feature size, since the enhanced field beneath the particles drops of rapidly with distance, and interrupting the exposure at an early stage will leave only very shallow and narrow exposed resist areas. Consequently, correspondingly smaller lateral sizes may be achieved by using shorter exposure times, provided that sufficiently thin resist layers are used to allow for exposure throughout the entire resist thickness.

The illustrated embodiment shows how resist can be locally exposed, but it is also to be expressly understood that a structure (e.g. a mask replica) can be produced using this same exposure technique using a lift-off process or other pattern transfer techniques.

Many alterations and modifications may be made by those having ordinary skill in the art without departing from the spirit and scope of the invention. Therefore, it must be understood that the illustrated embodiment has been set forth only for the purposes of example and that it should not be taken as limiting the invention as defined by the following claims.

For example, while conductive, spherical nanoparticles have been described, any structure with dimensions of similar magnitude and which exhibits a near-field enhancement effect can be substituted, even though such a structure is not a particle, conductive nor spherical. For example, it is expressly contemplated that the mask will have specialized nanostructures formed by conventional lithography or other technologies now known or later devised for the purpose of making a nanoelectromechanical device or structure (NEMS). These specialized nanostructures will then be employed as a mask to activate the resist film by near-field enhancement, such as by using plasmon resonance.

Although the illustrated embodiment is best implemented using nanoparticles made of materials with high polarizability and low electron scatter times, such as Ag and Au nanoparticles, field enhancement can be achieved near any polarizable object, since polarizability implies charge movement, and the moving charges can be made to oscillate at their resonant frequency.

For example, notwithstanding the fact that the elements of a claim are set forth below in a certain combination, it must be expressly understood that the invention includes other combinations of fewer, more or different elements, which are disclosed in above even when not initially claimed in such combinations.

The words used in this specification to describe the invention and its various embodiments are to be understood not only in the sense of their commonly defined meanings, but to include by special definition in this specification structure, material or acts beyond the scope of the commonly defined meanings. Thus if an element can be understood in the context of this specification as including more than one meaning, then its use in a claim must be understood as being generic to all possible meanings supported by the specification and by the word itself.

The definitions of the words or elements of the following claims are, therefore, defined in this specification to include not only the combination of elements which are literally set forth, but all equivalent structure, material or acts for performing substantially the same function in substantially the same way to obtain substantially the same result. In this sense it is therefore contemplated that an equivalent substitution of two or more elements may be made for any one of the elements in the claims below or that a single element may be substituted for two or more elements in a claim. Although elements may be described above as acting in certain combinations and even initially claimed as such, it is to be expressly understood that one or more elements from a claimed combination can in some cases be excised from the combination and that the claimed combination may be directed to a subcombination or variation of a subcombination.

Insubstantial changes from the claimed subject matter as viewed by a person with ordinary skill in the art, now known or later devised, are expressly contemplated as being equivalently within the scope of the claims. Therefore, obvious substitutions now or later known to one with ordinary skill in the art are defined to be within the scope of the defined elements.

The claims are thus to be understood to include what is specifically illustrated and described above, what is conceptionally equivalent, what can be obviously substituted and also what essentially incorporates the essential idea of the invention.

We claim:

1. A method for performing nanolithography comprising:
providing a mask having conductive nanostructures disposed thereon, the nanostructures having a plasmon resonance frequency;
disposing the mask at least in close proximity to a resist layer;
illuminating the nanostructures with light at or near the frequency of the plasmon resonance frequency of the nanostructures to modify adjacent portions of the resist layer by enhanced exposure; and
developing the resist layer to define plasmon printed, subwavelength pattern in the resist layer.

2. The method of claim 1 where illuminating the nanostructures with light comprises illuminating the nanostructures at a glancing angle.

3. The method of claim 2 where illuminating the nanostructures at a glancing angle comprises illuminating the nanostructures at an angle to the normal of the resist layer.

4. The method of claim 1 where providing a mask having conductive nanostructures disposed thereon comprises providing a mask having Ag particles selectively disposed thereon or embedded therein with an average diameter of tens of nm or less.

5. The method of claim 1 where providing a mask having conductive nanostructures disposed thereon comprises providing a mask having polarizable particles selectively disposed thereon with an average diameter of tens of nm or less.

6. The method of claim 1 where illuminating the nanostructures with light comprises illuminating the nanostructures with p-polarized light.

7. The method of claim 1 where developing the resist layer to define plasmon printed, subwavelength pattern in the resist layer comprises printing a pattern with features as small as λ/10 where λ is the wavelength of the light.

8. The method of claim 1 where developing the resist layer to define plasmon printed, subwavelength pattern in the resist layer comprises printing a pattern with features as small as λ/20 where λ is the wavelength of the light.

9. The method of claim 1 further comprising providing a smooth resist layer on which plasmon printing is performed.

10. The method of claim 1 where providing a smooth resist layer comprises providing a resist layer having a thickness and a smoothness such that surface roughness of the resist layer does not cause the thickness of the resist layer to exceed the depth of enhanced exposure over a substantial portion of the resist layer.

11. The method of claim 1 where providing a mask having conductive nanostructures disposed thereon comprises disposing nanostructures having an average diameter equal to or less than 40 nm.

12. The method of claim 1 where illuminating the nanostructures with light comprises illuminating the nanostructures with light at visible frequencies.

13. The method of claim 1 where illuminating the nanostructures with light at or near the frequency of the plasmon resonance frequency of the nanostructures to modify adjacent portions of the resist layer by enhanced exposure comprises illuminating a resist layer with sensitivity to light at or near the frequency of the plasmon resonance frequency of the nanostructures.

14. An apparatus for performing nanolithography comprising:
a mask having conductive nanostructures disposed thereon, the nanostructures having a corresponding plasmon resonance frequency;
a resist layer disposed at least in close proximity to the mask;
a light source with a frequency at or near the frequency of the plasmon resonance frequency of the nanostructures to modify adjacent portions of the resist layer by enhanced exposure; and
means for developing the resist layer to define plasmon printed, subwavelength pattern in the resist layer.

15. The apparatus of claim 14 where the light source is arranged and configured relative to the nanostructures to illuminate the nanostructures at a glancing angle.

16. The apparatus of claim 14 where the conductive nanostructures are polarizable particles selectively disposed on the mask with an average diameter of tens of nm or less.

17. The apparatus of claim 14 where the conductive nanostructures are Au or Ag particles selectively disposed on the mask with an average diameter of tens of nm or less.

18. The apparatus of claim 14 where the light source illuminates the nanostructures with p-polarized light.

19. The apparatus of claim 14 where the means for developing the resist layer to define plasmon printed, subwavelength pattern in the resist layer comprises means for printing a pattern with features at least as small as λ/10 where λ is the wavelength of the light.

20. The apparatus of claim 14 where the means developing the resist layer to define plasmon printed, subwavelength pattern in the resist layer comprises means for printing a pattern with features at least as small as λ/20 where λ is the wavelength of the light.

21. The apparatus of claim 14 where the resist layer is a smooth layer on which plasmon printing is performed.

22. The apparatus of claim 14 where the resist layer has a thickness and a smoothness such that surface roughness of the resist layer does not cause the thickness of the resist layer to exceed the depth of enhanced exposure over a substantial portion of the resist layer.

23. The apparatus of claim 14 where the nanostructures have an average diameter equal to or less than 40 nm.

24. The apparatus of claim 14 where the light source illuminates the nanostructures at visible frequencies.

25. The apparatus of claim 14 where the resist layer comprises a photoresist layer having a sensitivity to light at or near the frequency of the plasmon resonance frequency of the nanostructures.
